(19) United States
(12) Patent Application Publication
(10) Pub. No.: US 2008/0116556 A1
(43) Pub. Date: May 22, 2008

(54) Package structure having through hole in spacer thereof

(75) Inventors: Che-Ya Chou, Kaohsiung (TW); Chi-Tsung Chiu, Kaohsiung (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/892,693

(22) Filed: Aug. 27, 2007

(30) Foreign Application Priority Data
Nov. 22, 2006 (TW) 95143251

(51) Int. Cl. H01L 23/48; H01L 23/02

(52) U.S. Cl. 257/686; 257/698; 257/E23.172; 257/E23.175

(57) ABSTRACT

A package structure having through hole in spacer is provided. The package structure includes a substrate, a first chip, a spacer and a sub-package. The first chip is disposed on the substrate, to which an active surface of the first chip is electrically connected. The spacer, having a first side, a second side and a through hole, is disposed on the first chip, wherein the first side is opposite to the second side, and the through hole connects the first side and the second side. The sub-package is disposed on the spacer and electrically connected to the substrate.

This application claims the benefit of Taiwan application Serial No. 095143251, filed Nov. 22, 2006, the subject matter of which is incorporated herein by reference.

### BACKGROUND OF THE INVENTION

1. Field of the Invention

The invention relates in general to a package structure, and more particularly to a package structure having through hole in spacer thereof.

2. Description of the Related Art

Package-in-package (PIP) packaging technology contributes to tridimensionally single-chip level package, in which tested inside stacked modules (ISM) are stacked on the basic assembly package (BAP). Thus, the multi-dimensional space is fully utilized, and different chips with hetero-technologies, different functions, operating voltages are integrated into a package.

Normally, a spacer is disposed between the basic assembly package (BAP) and the inside stacked module (ISM) to provide a platform for ISM and generate a space for wire bonding. To highlight the key elements, a portion of elements are omitted in FIG. 1. Referring to FIG. 1, a chip 16 is stacked on a chip 14 and wire bounded to the chip 14 and a substrate 12, and a spacer 18 is disposed on the remaining surface of the chip 14. As the chips are normally rectangles with different sizes, the most common spacer 18 is an L-shaped structure or an U-shaped structure complementary to the shape of the chip. Besides, the spacer 18 is made from a solid and insulating material providing a stable platform for other modules or packaged semiconductor element (not illustrated) to stack on. At last, a sealant (not illustrated) is applied and a package is formed.

However, when a liquid sealant flows to the space between the chip 16 and the spacer 18, the gas is very likely to be contained at the inner corner of the spacer 18, and forms a void 20 in the solid sealant. Such defect will deteriorate the reliability of the package structure, and may cause further problem when temperature changes during the subsequent manufacturing processes or service.

### SUMMARY OF THE INVENTION

The invention is directed to a package structure having a through hole for ventilating the gas completely during sealing process.

According to a first aspect of the present invention, a package structure having a through hole in spacer is provided. The package structure includes a substrate, a first chip, a spacer and a sub-package. The first chip is disposed on the substrate, to which an active surface of the first chip is electrically connected. The spacer, having a first side, a second side and a through hole, is disposed on the first chip, wherein the first side is opposite to the second side, and the through hole penetrates through the first side and the second side. The sub-package is disposed on the spacer and electrically connected to the substrate.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a partial top view of a conventional package-in-package (PIP) package structure;

FIG. 2 is a side view of a package structure according to a preferred embodiment of the invention;

FIG. 3 is a partial top view of the package structure of FIG. 2;

FIG. 4 is a side view of a spacer of FIG. 3; and

FIG. 5 is a partial top view of a package structure according to another preferred embodiment of the invention.

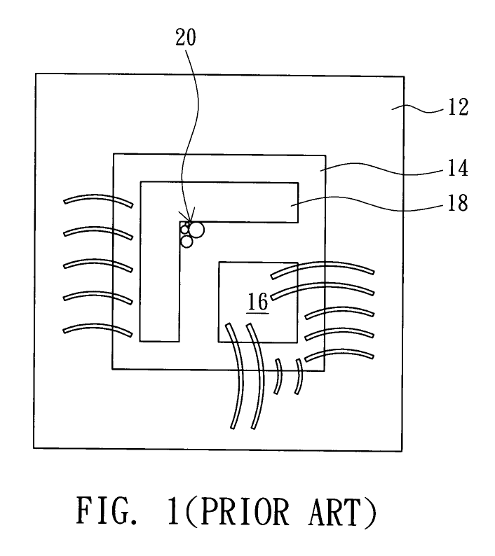

### DETAILED DESCRIPTION OF THE INVENTION

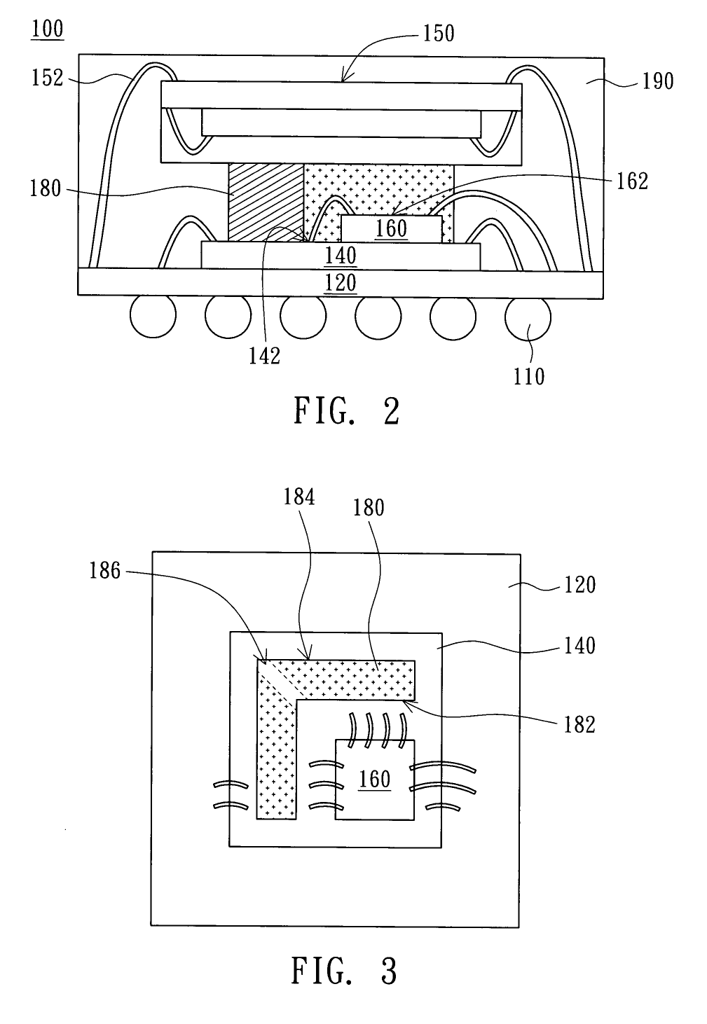

Referring to FIG. 2, a side view of a package structure according to a preferred embodiment of the invention is shown. In the present embodiment of the invention, the package structure 100 is a package-in-package (PIP) structure including a substrate 120, a first chip 140, a second chip 160, a spacer 180 and a sub-package 150. The first chip 140 is disposed on the substrate 120 to which an active surface 142 of the first chip is electrically connected. The package structure 100 further comprises an adhesive layer disposed between the first chip 140 and the substrate 120.

The second chip 160 is disposed on the first chip 140. An active surface 162 of the second chip 160 is electrically connected to the substrate 120 and the active surface 142 of the first chip 140. The package structure 100 further comprises a plurality of wires for electrically connecting the first chip 140 and the second chip 160.

The spacer 180 is disposed on the first chip 140. The sub-package 150 is disposed on the spacer 180 and electrically connected to the substrate 120. The height of the spacer 180 is greater than that of the second chip 160, so that the sub-package 150 is separated from the second chip 160 by an interval.

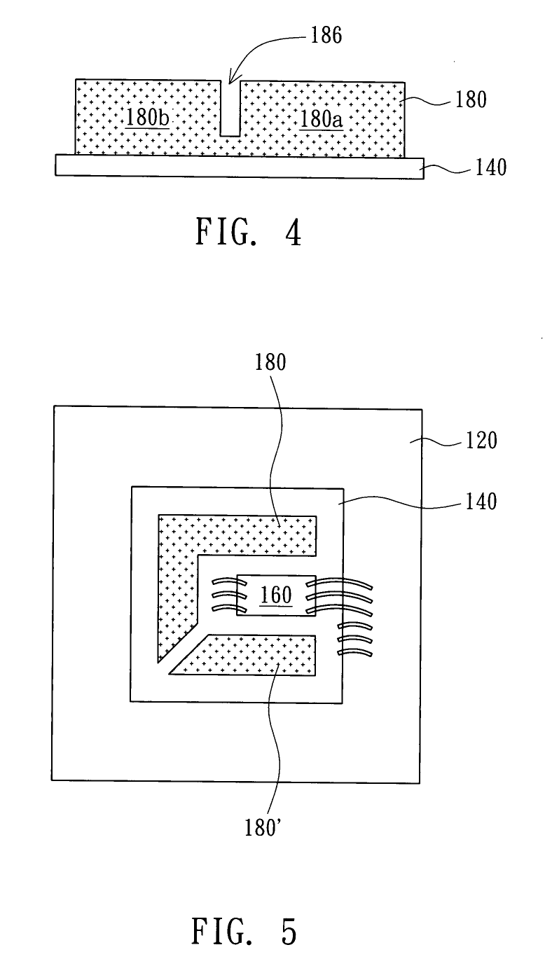

Referring to FIG. 3, a partial top view of the package structure of FIG. 2 is shown. The spacer 180 has a first side 182, a second side 184 and a through hole 186. The first side 182 is opposite to the second side 184, and the through hole 186 connects the first side 182 and the second side 184. Referring to FIG. 4, a side view of a spacer of FIG. 3 is shown. The spacer 180 includes a first portion 180a and a second portion 180b, and the first portion 180a forms a pre-determined angle with the second portion 180b. The through hole 186 is preferably disposed at the junction between the first portion 180a and the second portion 180b. For example, if the spacer 180 is an L-shaped structure, then the through hole 186 of the spacer 180 is disposed at a turn of the L-shaped structure; if the spacer 180 is an U-shaped structure, then the through hole 186 of the spacer 180 is preferably disposed at a turn of the U-shaped structure.

Moreover, the spacer 180 could be made of a gas permeable material or a porous material.

Referring to FIG. 5, a partial top view of a package structure according to another preferred embodiment of the invention is shown. The package structure 100 further includes another spacer 180′ disposed on the first chip 140 and is separated from the spacer 180 by an interval. The gas could be ventilated between two opposite sides of the spacer 180 through the through hole 186, porous material or gaps between two spacers 180 and 180′, so that the gas will not be contained at the turning corner of the spacer 180 and voids will not be formed in the sealant during the sealing process

Referring to FIG. 2, the sub-package 150 could be a wire-bonded type package structure, a flipchip type package structure or a package structure of other types. The package structure 100 further includes a conductive wire 152 and a sealant 190. The conductive wire 152 is for electrically connecting the sub-package 150 and the substrate 120. The sealant 190 is for encapsulating the substrate 120, the first chip 140, the second chip 160, the spacer 180, the sub-package 150 and the conductive wire 152. The sealant 190, for example, is an epoxy. The package structure 100 further includes a plurality of solder balls 110 disposed under the substrate 120.

During the sealing process, the gas is ventilated from the package structure 100 through the mechanism of the through hole 186, porous material or gaps between two spacers 180 and 180′, and the liquid sealant 190 flows between two opposite sides of the spacer 180 and finally fills the through hole 186. Thus, the gas will not be contained at the corner of the spacer 180 or remained in the through hole 186, porous material or gaps, and voids will not be formed in the sealant 190. The above design of the spacer avoids defects occurring to the package structure, hence increasing the reliability of the package structure.

According to the package structure disclosed in the above embodiments of the invention, the spacer of the package structure comprises a through hole, porous material or gaps. During the sealing process, the gas is ventilated from the package structure through the through hole, porous material or gaps. Thus, the gas will not be contained at the corner of the spacer, lest voids might be formed in the sealant. The above design of the spacer avoids defects occurring to the package structure, hence increasing the reliability of the package structure.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package structure, comprising:
a substrate;
a first chip disposed on the substrate and having an a active surface electrically connected to the substrate;
a spacer disposed on the first chip and having a first side, a second side and a through hole, wherein the first side is opposite to the second side, the through hole connects the first side and the second side; and
a sub-package disposed on the spacer and electrically connected to the substrate.

2. The package structure according to claim 1 further comprising a plurality of solder balls disposed under the substrate.

3. The package structure according to claim 1, wherein the spacer is made of a gas permeable material.

4. The package structure according to claim 3, wherein the spacer is made of a porous material.

5. The package structure according to claim 1, wherein the spacer comprises a first portion and a second portion forming a pre-determined angle with the first portion, the through hole disposed at a junction between the first portion and the second portion.

6. The package structure according to claim 5, wherein the spacer is an L-shaped structure.

7. The package structure according to claim 6, wherein the through hole of the spacer is disposed at a turn of the L-shaped structure.

8. The package structure according to claim 5, wherein the spacer is an U-shaped structure.

9. The package structure according to claim 8, wherein the through hole of the spacer is disposed at a turn of the U-shaped structure.

10. The package structure according to claim 1 further comprising another spacer disposed on the first chip and separated from the spacer by an interval.

11. The package structure according to claim 1 further comprising an adhesive layer disposed between the first chip and the substrate.

12. The package structure according to claim 1 further comprising a second chip disposed on the first chip and having an active surface electrically connected to the active surface of the first chip and the substrate;
wherein the height of spacer is greater than that of the second chip, so that the sub-package is separated from the second chip by an interval.

13. The package structure according to claim 12 further comprising a plurality of wires for electrically connecting the first chip and the second chip.

14. The package structure according to claim 1, wherein the sub-package is a wire-bonded type package structure.

15. The package structure according to claim 1, wherein the sub-package is a flip-chip type package structure.

16. The package structure according to claim 1 further comprising:
a conductive wire for electrically connecting the sub-package and the substrate; and
a sealant for encapsulating the substrate, the first chip, the second chip, the spacer, the sub-package and the conductive wire.

17. The package structure according to claim 16, wherein the sealant is an epoxy.

18. The package structure according to claim 16, wherein the sealant fills up the through hole.

19. The package structure according to claim 1 is a package-in-package (PIP) structure.
